(19) United States
(12) Patent Application Publication
(10) Pub. No.: US 2008/0206970 A1
(43) Pub. Date: Aug. 28, 2008

(54) Production Of Polycrystalline Silicon

(76) Inventors: Franz Hugo, Aschaffenburg (DE); Lyle C. Winterton, Butte, MT (US)

Correspondence Address: KLARQUIST SPARKMAN, LLP, 121 SW SALMON STREET, SUITE 1600, PORTLAND, OR, 97204, US

(21) Appl. No.: 11/911,101

(22) PCT Filed: Apr. 6, 2006
(86) PCT No.: PCT/US2006/012882

§ 371 Date: Oct. 9, 2007

(30) Foreign Application Priority Data
Apr. 10, 2005 (DE) 10 2005 016 549.4

(51) Int. Cl. H01L 21/36; C23C 16/00

(52) U.S. Cl. 438/488; 118/724; 257/E21.461

(57) ABSTRACT

Polysilicon is deposited onto a tube or other hollow body. The hollow body replaces the slim rod of a conventional Siemens-type reactor and may be heated internally with simple resistance elements. The hollow body diameter is selected to provide a surface area much larger than that of a silicon slim rod. The hollow body material may be chosen such that, upon cooling, deposited polysilicon readily separates from the hollow body due to differences in contraction and falls into a collection container.

### BACKGROUND

Polycrystalline silicon, or polysilicon, is a critical raw material for the photovoltaic industry. Presently, a bottleneck factor for the entire photovoltaic industry is providing this emerging, fast growing industry with sufficient supplies of polysilicon to meet the demand.

Up to this time, solar grade silicon has been predominately obtained from surpluses of the semiconductor industry. However, a few manufacturers of semiconductor grade silicon do commercially produce solar grade material using conventional processes. One conventional process transforms metallurgical silicon into silane or a polysilane or one of the chlorosilane compounds. The silane, polysilane or chlorosilane is pyrolyzed in a Siemens-type reactor forming polysilicon of high grade purity.

In the Siemens process, polysilicon rods are produced by the pyrolytic decomposition of a gaseous silicon compound, such as silane or a polysilane or a chlorosilane, on a filament substrate also called a slim rod. These slim rods are typically made of polysilicon to assure product purity levels.

The process comprises:
a) An even number of electrodes are attached to a base plate, each electrode can have a starting filament (slim rod) attached. These silicon slim rods are typically less than 10 mm diameter.
b) The slim rods are joined in pairs by a connecting bridge. Each bridge is a piece of slim rod material and is joined to two slim rods. Each set of two slim rods and a bridge thus is an inverted U-shaped member, commonly referred to as a hairpin. For each hairpin assembly, an electrical pathway is formed between a pair of electrodes within the reactor. An electrical potential applied to the electrodes can thus supply current required to heat the attached hairpin resistively.
c) The hairpins are contained in a bell jar enclosure that mates with the base plate to define a batch reactor allowing operation under vacuum or positive pressure conditions.
d) A gaseous silicon precursor compound and other gases, as necessary, are fed into the reactor.
e) The U-shaped members are electrically heated to a temperature sufficient to effect decomposition of the gaseous precursor compound and simultaneous deposition of the semiconductor material onto the hairpins (chemical vapor deposition or CVD), thereby producing U-shaped polysilicon rods of substantial diameter.
f) Any by-product gases and unreacted precursor compounds are exhausted from the reactor.

The principles of design of present state of the art reactors for the pyrolysis of silane and chlorosilanes are set forth in, for example, U.S. Pat. Nos. 4,150,168; 4,179,530; 4,724,160; and 4,826,668.

As the growth process begins, slim rods (typically less than 10 mm diameter) have a small fraction of the exposed heated surface area that the rods will have at the end of the growth process when the rods are fully grown. The instantaneous feed rate of silane, polysilane or chlorosilane compound used as reactor feed gas is limited to provide what the rod surface area is capable of consuming. Hence, reactor feed gas typically starts at a low mass flow rate when the slim rods are small and is increased as the surface area of the growing rod increases. Therefore, the average production rate is the summation of the instantaneous growth rates at each diameter. Also, the surface area available for reaction limits the capacity of any Siemens-type reactor.

Overflowing of silane, polysilane or chlorosilane feed gas increases kinetic decomposition by increasing the concentration of feed within the reaction vessel. However, it also causes unreacted feed gas to be exhausted from the reactor. The unreacted exhausted silane, polysilane or chlorosilane will be either wasted or may be recovered using an expensive gas-separation and recovery process. The costs of unreacted feed gas wasting or recovery are weighed against the kinetic rate gains of overfeeding and an optimum is selected. This optimum typically requires that the silane, polysilane or chlorosilane feed rate is low in the beginning of the growth process and higher at the end.

Upon electrical starting of the slim rod U-shaped member or hairpin, often times the fragile polysilicon members will break due to thermal stresses as the member is electrically heated from room temperature to decomposition temperature. Also, long thin slim rod elements will bend and flex as the natural convective currents of reactor gases pass up the heated slim rod and back down the walls. This flexing can cause the fragile elements to break. Depending on the length and diameter of the slim rods, the speed at which the rod temperature is raised and the configuration of the bridge to slim rod connection, the frequency of breakage can be very high.

If any U-shaped slim rod element breaks, the reactor must be inerted, opened and the broken members replaced before the process can be restarted. Other rods in the electrical circuit containing the broken slim rod may also have to be replaced, resulting in cumulative losses of production.

Conventional Siemens reactors use complicated and expensive power supplies. When the slim rods are small, these supplies must provide a high voltage and low amperage because of the high electrical resistance of the small slim rod. The rod resistance decreases as the rod diameter increases so that at the end of the rod-growth cycle, rod surface temperature is maintained by providing a low level of voltage and a high level of amperage relative to what was required when the slim rods were small. A power supply with this capability is complicated and expensive.

When rods have reached their final diameter, starting a new reactor batch is a time consuming process. First, the reaction chamber must be inerted by removing reactant and product gases. This is typically done with either pressure swings or through-purging using argon or nitrogen. Simultaneous to the reactor vessel inerting, rods must cool down before they can be handled. Rod cool down requires between four to ten hours depending on the decomposition temperature and the diameter of the rod. Upon rod cooling, the reaction vessel is opened and rods are removed. Upon rod removal, the interior of the reactor is cleaned and the new slim rods must be assembled to start the next batch. Before the next batch process can be started, the reactor interior volume must again be inerted.

The processes of inerting, cooling, harvesting, new slim rod setting and re-inerting are time consuming steps that typically consume between 5 to 15% of the available reactor decomposition time.

### SUMMARY

The present invention relates to apparatus and methods wherein, instead of using heated silicon slim rods, hollow tubes or other hollow bodies are installed in the Siemens reactor, which bodies can be heated from within causing the tube outer surface temperature to reach the deposition temperature normally used for CVD. The hollow bodies best are sealed, for example with end caps, such that process gasses are not allowed to enter the inner diameter volume where heating elements reside.

The silicon, provided by the disassociation of a silicon-bearing gas such as silane, polysilane, or chlorosilane, deposits itself on the outside of the deposition tube or hollow body.

An advantage of this method is that the hollow body can be of any diameter much larger than that of a conventional slim rod and, therefore, can have an effective circumferential surface area that is many times greater than that of a slim rod. Because Siemens reactor productivity is limited by the surface area available for the CVD reaction, productivity is increased. This advantage results because the kinetic decomposition rate of silicon-bearing gases such as silane or any chlorosilane is linear with respect to the heated surface area provided.

The shape of the hollow body may be any geometrical shape such that heated surface area is increased and polysilicon product removal is improved. But certain shapes may be advantageous as described herein.

Another advantage is that the hollow body need not be attached to a bridge and again to a second slim rod forming a U-shaped element or hairpin as is required in a conventional Siemens reactor. Unlike the conventional Siemens reactor, the hollow body, being heated from within using resistance elements, does not require an electrical path for conduction heating to a second rod. All circuitry can be contained within the hollow body.

Because the hollow body is rigid and attached to the reactor vessel, it cannot break or fall over as do the conventional U-shaped members or hairpins of a conventional Siemens reactor.

Another advantage is that the decomposition process can be carried out using a much simpler power supply for hollow body heating than what would be required by conventional Siemens-type technology. A hollow body that is heated from within can be heated with resistance elements, which elements are simple and inexpensive. The hollow body outer surface temperature is controlled by turning elements on and off with proportional control. The voltage and amperage requirement of any internal resistance heater element remains constant when in operation.

Another advantage is that after accumulating polysilicon on the outer surface of the hollow body (after reaching a desired polysilicon thickness), the accumulated polysilicon can be disengaged from the outer circumference of the hollow body and following the disengagement fall by gravity. A collection container can be positioned below the hollow body to receive the falling polysilicon. After receiving a load of silicon, the collection container can be isolated from the reaction chamber via a slide valve and the polysilicon product can be removed from the collection chamber during a time period that does not interfere with the polysilicon growth process taking place in the reaction chamber.

The disengagement of the polysilicon from the hollow body will occur due a difference in thermal contraction between the hollow body material and the deposited polysilicon when the hollow body inner heaters are turned off and the hollow body and the polysilicon deposition layers are allowed to cool.

Recovery of the fully grown polysilicon tube can be accomplished by halting the silane feed and the power source and cooling the hollow body using a gaseous medium from within the hollow body. Because of the difference in coefficients of thermal expansion between the hollow body and the growth layer of polysilicon, polysilicon expels itself from the substrate and falls into the collection container. The collection container can then be isolated from the reaction vessel using a slide-valve or other suitable isolation whereupon the reactor is immediately available for decomposition of additional silicon-bearing gas. Meanwhile the collection container can be inerted, cooled, and manually unloaded while the reactor is in operation.

One variation is to use a hollow body having an outer surface in the shape of the frustum of a cone with the large diameter oriented toward the bottom. If upon cooling the polysilicon does not completely detach from the hollow body, this configuration can allow remaining polysilicon to slip downwardly so that the hollow body wedgingly engages the remaining polysilicon. Subsequent reheating of the hollow body causes hollow body expansion which induces fracture of the polysilicon and will thereby assist in total expulsion of the polysilicon from the hollow body to the collection container.

Because the polysilicon expels itself from the hollow tube upon cooling, the reactor vessel interior need not be inerted. Because the polysilicon will not be exposed to air or to personnel, cooling for personnel protection is not required. The hollow body provides an outer surface for silicon deposition as does a slim rod in the conventional Siemens process, but the hollow body is advantageous in that it does not require replacement. Reactor interior cleaning is not required and the growth cycle can be immediately started again.

It is estimated that 90% of the time typically required to shutdown, cool-down, inert, harvest, set-up, and re-inert a conventional Siemens reactor can be saved using hollow bodies as described herein.

When depositing polysilicon directly upon a hollow body made of metal or other material, the innermost layer of the deposited polysilicon can be contaminated by the substrate material. To minimize this contamination layer, the reaction procedure can be altered in that it first operates in a CVD mode to add a diffusion barrier layer directly to the hollow body followed by CVD deposition of polysilicon over the diffusion barrier.

The foregoing and other features and advantages will become more apparent from the following detailed description, which proceeds with reference to the accompanying figures.

### BRIEF DESCRIPTION OF THE DRAWINGS

FIG. 1 is a vertical cross-sectional schematic view of a reactor containing a hollow body that is cylindrical and that enters the reaction volume from the bottom.

FIG. 2 is a vertical cross-sectional schematic view of a reactor containing a hollow body that is shaped like the frustum of a cone and that enters the reaction volume from the top.

### DETAILED DESCRIPTION

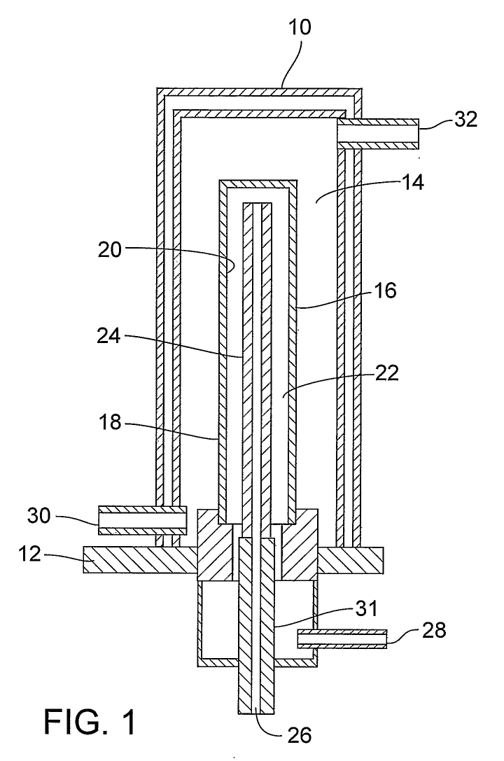

FIG. 1 shows a silicon production apparatus that includes a jacketed cover or bell 10 which rests on a base 12 to provide a gas tight vessel that defines a reaction volume or chamber 14. A substrate body 16 is supported within the chamber 14. In particular the body 16 rests on a portion of the base 12. The body 16 has an outer surface 18 that is oriented to receive a layer of polycrystalline silicon deposited from precursor gas in the reaction chamber 14. For best efficiency, the outer surface 18 will have a horizontal cross-sectional dimension that is at least 25 mm. The body 16 also has an inner surface 20 that defines a cavity 22 which receives a heat source 24. The cavity 22 is isolated from the reaction chamber 14 so that reactant gasses cannot enter the cavity. The vessel defines an inlet 26 located to admit purge gas into the cavity 22 and an outlet 28 to vent purge gas. Reactant gas is supplied to the chamber 14 via a reaction gas inlet 30 and is vented from the chamber via a reaction gas outlet 32.

The illustrated substrate body 16 is a hollow body that is shaped as a cylinder with an outer diameter of 105 mm. The hollow body 16 extends generally vertically and has a substantially circular horizontal cross-section. The illustrated hollow body 16 is composed of molybdenum, but could be constructed of tungsten, carbon or any of several other materials, such as an INCOLOY® high temperature metal alloy, or a combination of materials. The body 16 will conveniently be of unitary construction and composed entirely of a single material, such as a metal or an alloy, but may comprise several parts, for example layers. The end cap portion of the body 16 may be formed with the side wall or may be separately formed and attached to seal the free end of the body. For the reactor to be self-harvesting as described herein, the substrate body 16 will have a coefficient of thermal expansion that differs sufficiently from that of polysilicon to cause mechanical separation to occur. Good results are achieved when a substrate body has a coefficient of thermal expansion that differs from that of polycrystalline silicon by a least 20%. The heat source 24 is a resistance heater received through an opening located at the bottom of the substrate body 16 and connected to a power source by a penetrating heater connection 31.

To form polycrystalline silicon, the reactor volume 14 is inerted, the hollow body 16 is heated by the resistance heater 24 to a temperature appropriate for chemical vapor deposition, and silicon-bearing gas is admitted through the reaction gas inlet 30. The silicon-bearing gas may be any of several types known for use in the CVD formation of polysilicon, including for example, one or more compounds selected from the group consisting of silane (SiH₄), disilane (Si₂H₆), higher order silanes (SinH₂H₂ₙ₊₂), dichlorosilane (SiH₂CI₂), trichlorosilane (SiHCl₃), silicon tetrachloride (SiCl₄), dibromosilane (SiH₂Br₂), tribromosilane (SiHBr₃), silicon tetrabromide (SiBr₄), diiodosilane (SiH₂I₂), triiodosilane (SiHI₃), and silicon tetraiodide (SiI₄).

The temperature chosen will depend on the silicon-bearing source gas selected. For example, 800° C. may be appropriate for silane and 1050° C. may be appropriate for trichlorosilane.

The silicon-bearing gas mass flow rate through the inlet 30 is adjusted to provide a specific concentration of reactant within the reaction vessel. This specific concentration may be set to be the concentration normally used for deposition onto a silicon slim rod of 7 mm diameter.

The heated length of the illustrated hollow body 16 is one meter. The area of the outer surface 18 of the hollow body is about fifteen times that of a 7 mm heated silicon slim rod of the same length. Kinetic expressions indicate that the decomposition rate of any silicon-bearing source gas is linear with the exposed heated surface area.

The instantaneous rate of decomposition of polysilicon onto the hollow body is about fifteen times the rate normally achieved when using a 7 mm slim rod. Polysilicon deposited on the hollow-body is allowed to grow to a thickness of 10 mm (from 105 mm to 115 mm) to yield about 2.7 kg of polysilicon. This is compared to a slim rod that grows from 7 mm to 47½ mm (average diameter is 27 ¼ nm) and also yields 2.7 kg of polysilicon. The ratio of the average surface areas during the entire growth cycle is 110/27¼ or about four. This ratio indicates that one can expect the average production of the hollow body reactor described above to be four times that of a slim-rod reactor grown under the conditions described above.

When depositing polysilicon directly upon a hollow body made of metal or other material, the innermost layer of the deposited polysilicon can be contaminated by the substrate material. To minimize this contamination layer, the reaction procedure can be altered in that it first operates in a CVD mode to add a diffusion barrier layer directly to the hollow body followed by CVD deposition of polysilicon over the diffusion barrier. This diffusion barrier layer can be comprised of SiN (silicon nitride) or SiC (silicon carbide) or any other compound that inhibits the hollow body material from diffusion into the polysilicon. Silicon nitride can be formed by CVD deposition of a silicon-bearing gas in the simultaneous presence of ammonium ions (NH₄⁺). Silicon carbide can be formed by CVD deposition of a silicon-bearing gaseous compound containing a methyl (—CH₃) group.

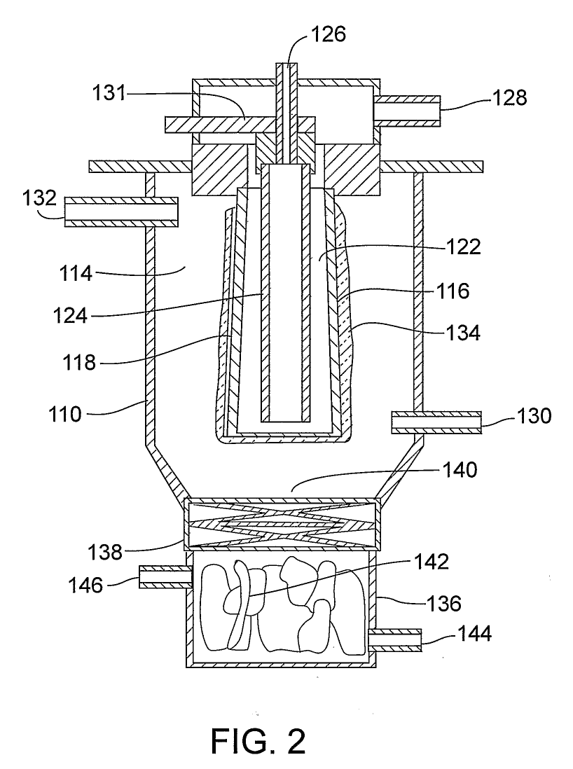

FIG. 2 shows another reactor arrangement, wherein comparable elements are numbered similarly to those show in FIG. 1 with the numbers incremented by 100. In the arrangement of FIG. 2, a hollow body 116 enters the reaction volume 114 from the top and is suspended from the top. A resistance heater 124, contained within a cavity 122 defined by the hollow body 116, likewise is suspended from above.

The type of hollow body illustrated has a side wall with an outer surface, at least a portion of which surrounds a vertical axis and flares downwardly with changes in elevation. In particular, the surface 118 is shaped like the frustum of a cone with a major diameter at the bottom of 115 mm and minor diameter at the top of 105 mm. Under the hollow body 116 is a valve 138 positioned to selectively open and close a vessel outlet 140 that communicates with a product collection container 136. The illustrate valve 138 is a slide valve, but another form of valve, such as a full port ball valve, could be used.

Polysilicon 134 is deposited on the hollow body 116 in a manner as described above. During the deposition of polysilicon, the slide valve 138 is closed, isolating the collection chamber 136 from the interior 114 of the reaction vessel so that gas inside the reaction vessel does not enter the collection chamber.

Gravity is used to assist product collection as deposited polysilicon 134 falls from the hollow body 116 into the collection container 136. When polysilicon deposited on the hollow body reaches an average outside diameter of 120 mm, internal heaters 124 are turned off. A nitrogen purge is started through a purge inlet 126 through the interior of the hollow body 116 to speed hollow body cooling. The slide valve 138 below the hollow body 116 is opened exposing the collection container 136.

As the hollow body 116 cools, it contracts to a different extent than the deposited polysilicon 134. For example, a molybdenum hollow body contracts more than does the polysilicon because the average linear coefficients of thermal expansion per ° C. for molybdenum and polysilicon are 4.9 (10⁻⁶) and 4.0 (10⁻⁶) respectively. Due to the differential, polysilicon separates from the hollow body 116 and either falls to the collection container 136 or slips downwardly on the hollow body.

If some or all of the polysilicon remains on the hollow body 116, the hollow body is heated again to about 800° C. to cause the hollow body to expand to a different extent than the polysilicon. The polysilicon breaks, e.g. because molybdenum expands more and faster than does the polysilicon, and the polysilicon falls to the collection container 136. The slide valve 138 is closed, after all the polysilicon 134 is separated from the hollow body 116. The collection container 136, containing fallen polysilicon fragments 142, thereby is isolated from the interior 114 of the reaction vessel. After the product is isolated in the collection container 136, the interior of the container can be purged of reactive gasses to facilitate harvest of the polysilicon product 142. Purging may be accomplished by feeding inert gas into the collection container 136 via a gas inlet 144, which causes an outflow of gas through an outlet 146.

The step of closing the slide valve 138 to isolate the collection container 136 is at the end a production cycle. Once the slide valve is closed, the reactor may be restarted for another cycle of polysilicon deposition.

### EXAMPLE

As an example, an internally heated molybdenum hollow body is configured within a reaction chamber as in FIG. 2. The hollow body is shaped as a frustum of a cone with the large diameter being 110 mm and the small diameter being 100 mm (average diameter is 105 mm). The slide valve is closed isolating the collection chamber from the reaction vessel. Silane is the silicon-bearing source gas. After inerting the reaction volume, the hollow body is heated to 800° C. The heated length of the hollow body is 1 meter. The silane feed gas mass flow rate is adjusted to provide a 1% silane concentration within the reaction vessel. The reaction vessel pressure is 26.5 psia.

Polysilicon is grown on the hollow body until the hollow body diameter has grown from an average 105 mm to an average 115 mm. The growth cycle yields 2.7 kg in 66 hours for an average resultant growth rate of 41.3 grams/hr. This is compared to polysilicon grown onto the 7 mm slim rod set at 800° C. and grown to 47.5 mm in 266 hours for an average growth rate of 10.1 g/hr. The growth rate ratio between the hollow 105-115 mm hollow body and the 7 to 47.5 mm slim rod is about 4. The ratio of average surface areas of 105 to 115 mm hollow body to 7 to 47.5 mm slim rod is also about 4. The difference in growth rate is caused by the difference in surface areas.

Upon reaching 115 mm average polysilicon diameter, the internal heaters are turned off. A nitrogen purge is started through the interior of the hollow body to assist in cooling. The slide valve below the hollow body is opened exposing the collection container.

As the hollow body cools, the molybdenum hollow body contracts more than does the polysilicon because the average linear coefficients of thermal expansion per ° C. for molybdenum and polysilicon are 4.9 (10⁻⁶) and 4.0 (10⁻⁶) respectively. The polysilicon separates from the molybdenum hollow body and either falls to the collection container or slips downwardly on the hollow body.

To discharge polysilicon from the hollow body, the hollow body is heated again to about 800° C. The polysilicon then breaks because the molybdenum expands more and faster than does the polysilicon and the polysilicon falls to the collection container. The slide valve is closed and the collection container is isolated from the reaction vessel.

The step of closing the slide valve to isolate the collection container ends the batch process. The reactor may now be restarted for another deposition cycle.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1. Silicon production apparatus comprising:
a reactor vessel that contains at least one reaction chamber and that defines an inlet for delivering a silicon-bearing gas into the chamber;
at least one substrate body supported within the chamber, the body defining a cavity and having a outer surface; and
a heat source located within the cavity and positioned to heat the outer surface so that silicon-bearing gas supplied into the reaction chamber will deposit polycrystalline silicon on the outer surface of the substrate body by chemical vapor deposition.

2. The apparatus of claim 1 wherein at least the outer surface of the substrate body is molybdenum.

3. The apparatus of claim 1 wherein at least the outer surface of the substrate body is carbon.

4. The apparatus of claim 1 wherein at least the outer surface of the substrate body is tantalum.

5. The apparatus of claim 1 wherein the substrate body has a coefficient of thermal expansion that differs from that of polycrystalline silicon by a least 20%.

6. The apparatus of claim 1 wherein the substrate body has a horizontal outer cross-sectional dimension that is greater than 25 mm.

7. The apparatus of claim 1 wherein the vessel defines an inlet located to admit purge gas into the cavity.

8. The apparatus of claim 1 further comprising a diffusion barrier layer on the surface of the substrate body such that the polycrystalline silicon is deposited on the diffusion barrier layer.

9. The apparatus of claim 1 wherein the substrate body defines an opening through which the heat source is received in the cavity.

10. Silicon production apparatus comprising:
a reactor vessel that contains at least one reaction chamber, that defines an inlet for delivering a silicon-bearing gas into the reaction chamber, and that defines a product outlet;
at least one substrate body that has an outer surface, is supported within the chamber above the elevation of the product outlet, and is located so that polycrystalline silicon which falls from the substrate body by gravity falls to the outlet;
a heat source positioned to sufficiently heat the outer surface so that silicon-bearing gas supplied into the reaction chamber will deposit polycrystalline silicon on the outer surface of the substrate body by chemical vapor deposition; and
a valve operable to open and close the product outlet.

11-12. (canceled)

13. Silicon production apparatus comprising:
a reactor vessel that contains at least one reaction chamber and that defines an inlet for delivering a silicon-bearing gas into the chamber;
at least one substrate body supported within the chamber, the body having an outer surface, at least a portion of which surface flares with changes in elevation; and
a heat source located to heat the outer surface so that silicon-bearing gas supplied into the chamber will deposit polycrystalline silicon on the outer surface of the substrate body by chemical vapor deposition.

14. The apparatus of claim 13 wherein the flared portion of the surface flares downwardly.

15. The apparatus of claim 13 wherein the flared portion of the surface is generally frustoconical.

16. A substrate body for use inside a Siemens reactor, the substrate body:
having a outer surface suitable to serve as a substrate to receive deposited polycrystalline silicon; and
defining a cavity that is sized, shaped, and located to receive a heat source to heat the outer surface.

17-25. (canceled)

26. A method for making a polycrystalline silicon by depositing polycrystalline silicon on a deposition surface inside a reactor, the method comprising:
providing inside a reactor at least one substrate body that defines a cavity and that has an outer surface;
supplying heat within the cavity to heat the outer surface; and
depositing polycrystalline silicon on the heated outer surface, by chemical vapor deposition of silicon due to thermal decomposition of a silicon-bearing gas, to grow a layer of polycrystalline silicon on the surface.

27. The method of claim 26 further comprising cooling the substrate body to cause the body to contract a different amount than the deposited polycrystalline silicon layer so that the polycrystalline silicon layer separates from the outer surface.

28. The method of claim 26 further comprising heating the substrate body to cause the body to expand to a different extent than the polycrystalline silicon layer so that the polycrystalline silicon layer separates from the outer surface.

29. The method of claim 26 further comprising, before depositing silicon onto the body, depositing a diffusion barrier layer onto the surface of the body so that the polycrystalline silicon deposits on the diffusion barrier layer.

30. The method of claim 29 further comprising forming the diffusion barrier layer by depositing silicon from a silicon-bearing gas in the simultaneous presence of ammonium ions (NH₄⁺) so that a diffusion barrier layer of SiN is formed.

31. The method of claim 29 further comprising forming the diffusion barrier layer by depositing silicon from a silicon-bearing gaseous compound containing a methyl (—CH₃) group so that a diffusion barrier layer of SiC is formed.
